(19) United States
(12) Patent Application Publication
(10) Pub. No.: US 2015/0090898 A1
(43) Pub. Date: Apr. 2, 2015

(54) ION SOURCE

(71) Applicants: Richard John Futter, Lower Hutt (NZ); Andreas Markwitz, Lower Hutt (NZ)

(72) Inventors: Richard John Futter, Lower Hutt (NZ); Andreas Markwitz, Lower Hutt (NZ)

(21) Appl. No.: 14/236,581

(22) PCT Filed: Aug. 3, 2012
(86) PCT No.: PCT/NZ2012/000137

§ 371 Date: Sep. 24, 2014

Related U.S. Application Data
(60) Provisional application No. 61/514,708, filed on Aug. 3, 2011.

(51) Int. Cl. H01J 37/08; H01J 37/317

(52) U.S. Cl. CPC H01J 37/08; H01J 37/3171; H01J 2237/002
USPC 250/423 R

(57) ABSTRACT

The invention provides an ion source comprising first and second cathode pole pieces spaced apart from one another to form a cavity therebetween, an edge of the first cathode pole piece being spaced apart from an edge of the second cathode pole piece to define an elongate cathode gap between the respective edges of the pole pieces, the elongate cathode gap having a longitudinal axis; at least one magnet arranged for magnetising the first and second cathode pole pieces with opposite magnetic polarities; an elongate anode located in the cavity, the anode being spaced apart from the first and second cathode pole pieces and having a longitudinal axis, the longitudinal axis of the elongate anode and the longitudinal axis of the elongate cathode gap substantially coplanar; a first electrical connection which extends from outside the cavity to the anode; and a gas feed conduit which extends from outside the cavity to inside the cavity for introducing a gas into the cavity.

### FIELD OF INVENTION

The present invention relates to methods and devices for the treatment of the inside wall surface of pipes and tubes. More particularly, but not exclusively, it relates to the chemical and physical modification of the surface of inner and/or outer pipe walls with high current ion beams from plasma ion sources. The invention also relates to methods and devices for producing new chemical and physical properties of pipes with ion implantation under backing pressure vacuum conditions.

### BACKGROUND TO THE INVENTION

Developments in pipeline modifications are sought to improve the lifetime of the inner walls. Incorporation of ‘alien’ atoms in metal and plastic surfaces improves the chemical and physical resistance of the pipes in industrial processes, such as geothermal pipelines and stainless steel pipelines in the food processing industries.

Methods have been developed to coat inner wall tubes of small diameter with chemical vapour deposition and anodic treatments. These methods are limited in their use because of the complexity of the technology and adhesion problems at the interface between the coating layer and the underlying wall material. Ion implantation is a proven technology to incorporate atoms of any chemical element in any solid material with high precision and in short time. Ion implantation provides an elegant way of altering surface properties, both chemically and physically.

Ion implantation is a surface modification process in which ions are accelerated as a beam of ions toward a substrate and injected into the near-surface region of the substrate. High-energy ions impact the surface with sufficient energy to form an alloy with the substrate at the surface. Ions typically penetrate the substrate to a depth of up to 0.1 μm.

In one ion implantation method, known as plasma source ion implantation (PSII), a gas is excited to form a plasma, and positively charged gaseous ions are extracted from the plasma and accelerated toward a substrate by a high potential difference.

Ion sources are described generally at http://www.plasmalab.ru/depos_ion.htm.

Construction of a specific anode layer ion source is described in André Anders, “Plasma and ion sources in large area coating: A review, Surface and Coatings Technology”, Volume 200, Issues 5-6, 21 Nov. 2005, pp 1893-1906.

The document http://www.rtftechnologies.org/physics/fusor-mark3-anode-layer-ion-source.htm describes scientific research and engineering carried out by Andrew Seltzman, a plasma physics graduate student at University of Wisconsin, Madison and a physics and electrical engineering graduate from Georgia Institute of Technology. This ion source comprises a circular anode concentrically mounted adjacent a circular central cathode pole and a circular outer cathode pole on the end of a cylindrical housing. A permanent rare earth magnet generates a magnetic field between the cathode poles. A gas is introduced into the housing and a high voltage supplied to the anode. The source emits an ion beam which is directed axially away from a circular gap between the cathode pole pieces.

Another anode layer ion source is described by Advanced Energy Industries, Inc. at http://www.advanced-energy.com/upload/File/White_Papers/SL-WHITE12-270-01.pdf. This linear ion source has an elongated ‘racetrack shaped’ emission slit at one face of the ion source housing. A gas manifold distributes gas evenly along the source. Permanent magnets create a magnetic field between soft iron cathode poles at the edges of the slit. The source emits a linear ion beam in a direction perpendicular to the plane of the emission slit.

Another linear anode layer ion source is described by Gencoa Limited at http://www.gencoa.com/1,18-Ion-source.htm. This ion source also has an elongate ion emission slit.

U.S. Pat. No. 5,296,714 to Treglio teaches a method and apparatus for ion modification of the inner surface of tubes by techniques such as ion implantation, ion mixing, and ion beam assisted coating. The apparatus includes a plasma source, a pair of opposing magnets and an anode-cathode array. Ions removed from the plasma are accelerated outwardly in a radial direction to impact the inner wall of a tube through which the apparatus is moved.

It is an object of at least one embodiment of the present invention to use ion implantation techniques for the inner wall finishing of existing pipes and pipelines to increase the operational lifetime of the pipes, and particularly, but not exclusively, at bends in the pipes or pipelines.

It is a further object of preferred embodiments of the present invention to address some of the aforementioned disadvantages of the prior art. An additional and/or alternative object is to at least provide the public with a useful choice.

The present invention provides the public, and particularly manufacturers of metal pipes and pipelines, with a useful choice for improving the lifetime of pipe and pipeline products with ion beam treatments.

In this specification where reference has been made to patent specifications, other external documents, or other sources of information, this is generally for the purpose of providing a context for discussing the features of the invention. Unless specifically stated otherwise, reference to such external documents is not to be construed as an admission that such documents, or such sources of information, in any jurisdiction, are prior art, or form part of the common general knowledge in the art.

### SUMMARY OF THE INVENTION

In a first aspect, the present invention provides an ion source comprising:
first and second cathode pole pieces spaced apart from one another to form a cavity therebetween, an edge of the first cathode pole piece being spaced apart from an edge of the second cathode pole piece to define an elongate cathode gap between the respective edges of the pole pieces, the elongate cathode gap having a longitudinal axis;
at least one magnet arranged for magnetising the first and second cathode pole pieces with opposite magnetic polarities;
an elongate anode located in the cavity, the anode being spaced apart from the first and second cathode pole pieces and having a longitudinal axis, the longitudinal axis of the elongate anode and the longitudinal axis of the elongate cathode gap substantially coplanar;
a first electrical connection which extends from outside the cavity to the anode; and
a gas feed conduit which extends from outside the cavity to inside the cavity for introducing a gas into the cavity.

Preferably, the at least one magnet is located in the cavity. More preferably, the at least one magnet is at least one permanent magnet, and/or is at least one electromagnet.

Preferably, the ion source has a central axis, and the longitudinal axis of the elongate cathode gap and the longitudinal axis of the elongate anode lie on the circumferences of respective concentric circles centred on the central axis. More preferably, the elongate cathode gap extends circumferentially through 360 degrees about the central axis, and/or the elongate anode extends circumferentially through 360 degrees about the central axis.

Preferably, the at least one magnet comprises a plurality of magnets located in the cavity, and the magnets are arranged in a circular array centred on the central axis for magnetising the first and second cathode pole pieces respectively with opposite magnetic polarities.

Preferably, a thermally-conductive heat sink body is clamped between the cathode pole pieces with opposite end faces of the heat sink body respectively in abutment with the first and second cathode pole pieces; each magnet is clamped between the first and second cathode pole pieces with a north pole face of each magnet in abutment with one cathode pole piece and a south pole face of each magnet in abutment with the other cathode pole piece; the magnets are located in respective cavities in the heat sink body; and the gas feed conduit comprises an internal passageway which extends substantially radially outward from a central location at one of the end faces of the heat sink body to multiple gas outlets at circumferentially-spaced locations at an outer circumferential face of the heat sink body.

More preferably, the anode is supported by at least one electrically insulating standoff, and the at least one standoff is supported by the heat sink body. Still more preferably, a heat extractor is held in abutment with one of the pole pieces, the heat extractor comprising a thermally conductive body with an internal passageway which extends between a coolant inlet and a coolant outlet which are located at a face of the heat sink body.

Preferably, segments of the elongate anode extend circumferentially about the central axis, and the ion source comprises a respective electrical connection extending from outside the cavity to each segment of the anode.

In a second aspect, the present invention provides a method of implanting ions at an inner wall surface of a tube or pipe, comprising
locating an ion source, according to the first aspect of the invention described above, inside a portion of the tube or pipe;
connecting a first voltage source to the or each electrical connection which extends from outside the cavity to the or each anode;
connecting a second voltage source to the first and second cathode pole pieces,
creating at least a partial vacuum in the portion of the tube or pipe;
introducing a gas into the cavity through the gas feed conduit;
ionising gas in the cathode gap to produce a plasma; and
directing gas ions from the plasma to the inner wall surface of the tube or pipe.

Preferably, the ion source is located coaxially with a longitudinal axis of the portion of the tube or pipe.

Preferably, the ion source is advanced axially along the tube or pipe.

Preferably, the elongate cathode gap extends circumferentially through 360 degrees about the central axis, the elongate anode extends circumferentially through 360 degrees about the central axis, and gas ions from the ion source are directed through 360 degrees simultaneously toward the full circumference of the inner wall surface of the tube or pipe.

Preferably, segments of the elongate anode extend circumferentially about the central axis, and the ion source comprises a respective electrical connection extending from outside the cavity to each segment of the anode, and the first voltage is selectively connected to one or more segments of the anode via the respective electrical connections to direct gas ions from the ion source through an arc of less than 360 degrees toward a portion of the circumference of the inner wall surface of the tube or pipe. More preferably, the portion of the tube or pipe is curved and the first voltage is selectively connected to one or more of the anode segments to direct gas ions toward the inner wall surface of the tube or pipe at an outer side of the curved portion of tube or pipe.

The term ‘comprising’ as used in this specification and claims means ‘consisting at least in part of’, that is to say when interpreting statements in this specification and claims which include that term, the features, prefaced by that term in each statement, all need to be present but other features can also be present. Related terms such as ‘comprise’ and ‘comprised’ are to be interpreted in similar manner.

As used herein the term “and/or” means “and” or “or”, or both.

The qualifiers “upper”, “lower”, “top”, “bottom”, “underside”, “topside”, “above”, and “below”, and the like, and “horizontal” and “vertical”, and the like, when used herein with reference to features as shown in the accompanying figures are for convenience and clarity of explanation, and are not to be construed as limiting the ion source, and/or its components, or the operation or use of the ion source, and/or its components, to any particular orientation, including, but not limited to, any orientation described herein and/or depicted in the accompanying figures.

As used herein “(s)” following a noun means the plural and/or singular forms of the noun.

### BRIEF DESCRIPTION OF THE DRAWINGS

Various aspects of ion sources and a method of using the ion sources are illustrated by way of example, and not by way of limitation, in the accompanying drawings, wherein:

FIG. 1 shows an isometric view of an ion source in accordance with the invention;

FIG. 2 shows a diametrical cross-sectional view of the ion source of FIG. 1;

FIGS. 3A to 3F, when taken together, show an exploded view of the ion source of FIGS. 1 and 2, with a left front quadrant portion of each major component of the ion source cut away to show a half cross-sectional view;

FIG. 3A shows a partly cross-sectioned isometric view of a first cathode pole piece of the ion source of FIGS. 1 and 2;

FIG. 3B shows a partly cross-sectioned isometric view of an anode of the ion source of FIGS. 1 and 2;

FIG. 3C shows a partly cross-sectioned isometric view of an array of permanent magnets of the ion source of FIGS. 1 and 2;

FIG. 3D shows a partly cross-sectioned isometric view of a gas manifold and an anode standoff of the ion source of FIGS. 1 and 2;

FIG. 3E shows a partly cross-sectioned isometric view of a second cathode pole piece of the ion source of FIGS. 1 and 2;

FIG. 3F shows a partly cross-sectioned isometric view of a coolant jacket of the ion source of FIGS. 1 and 2;

FIG. 4 shows an isometric view of the underside of the first cathode pole piece of FIG. 3A;

FIG. 5 shows a cross-sectional view of the gas manifold of FIG. 3D, sectioned at the horizontal plane labelled V-V in FIG. 3D; and

FIG. 6 shows a cross-sectional view of the coolant jacket of FIG. 3F, sectioned at the horizontal plane labelled VI-VI in FIG. 3F.

### DETAILED DESCRIPTION

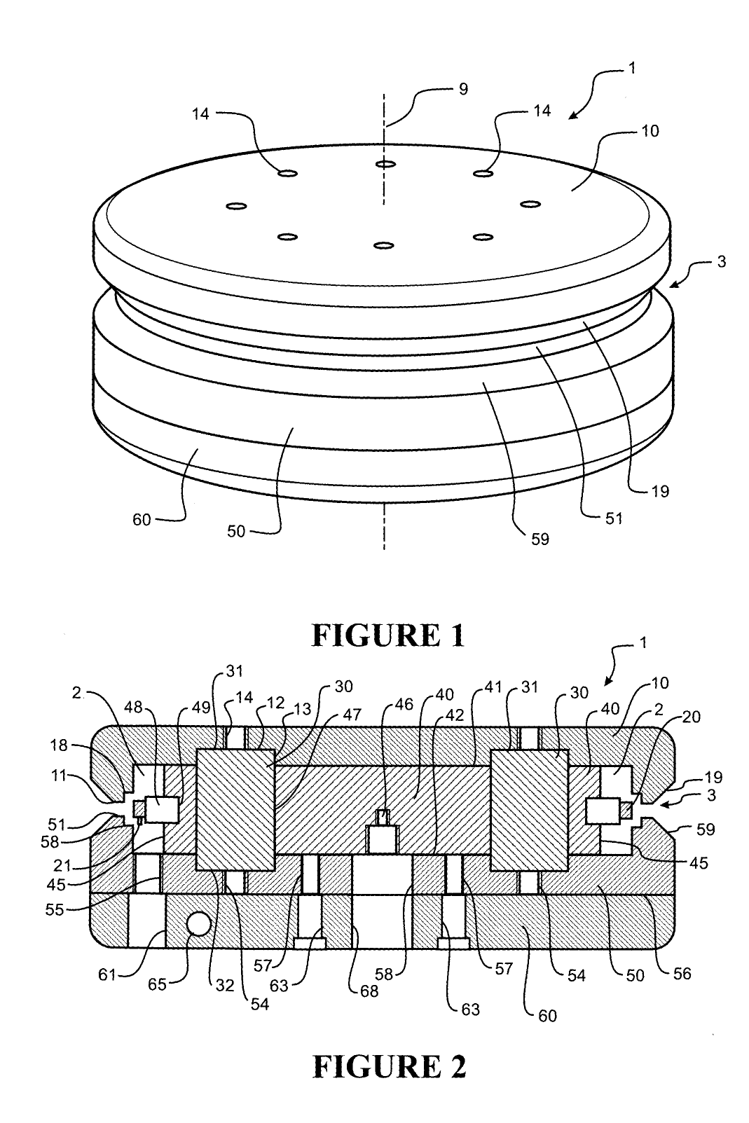

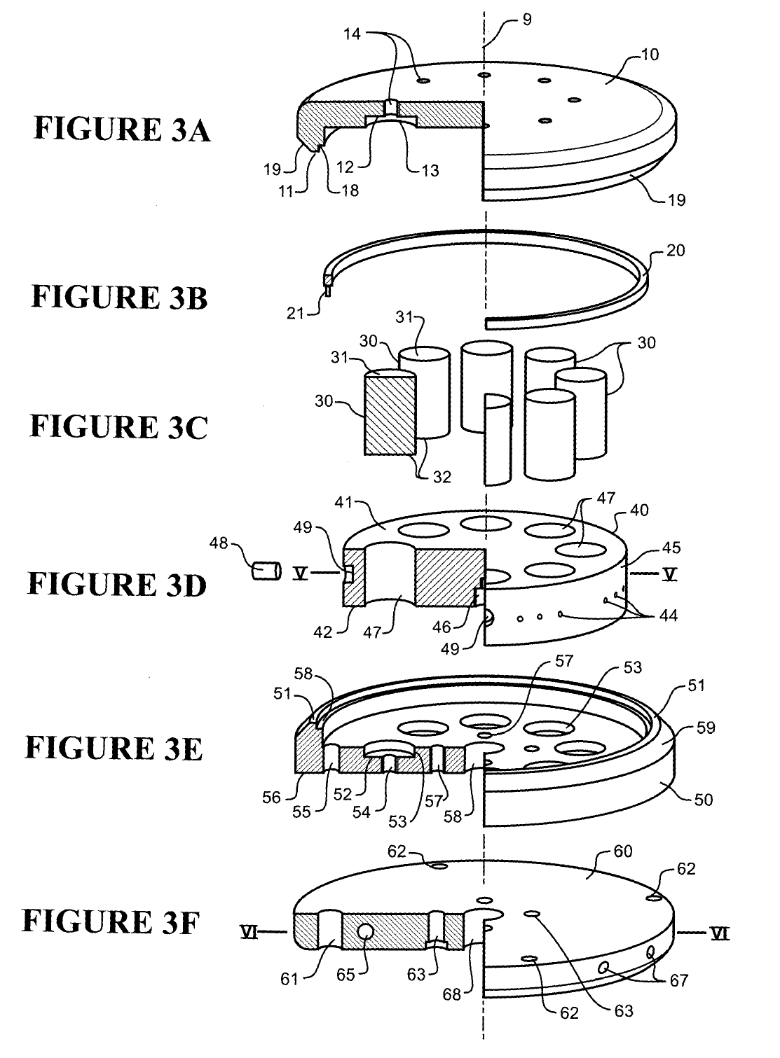

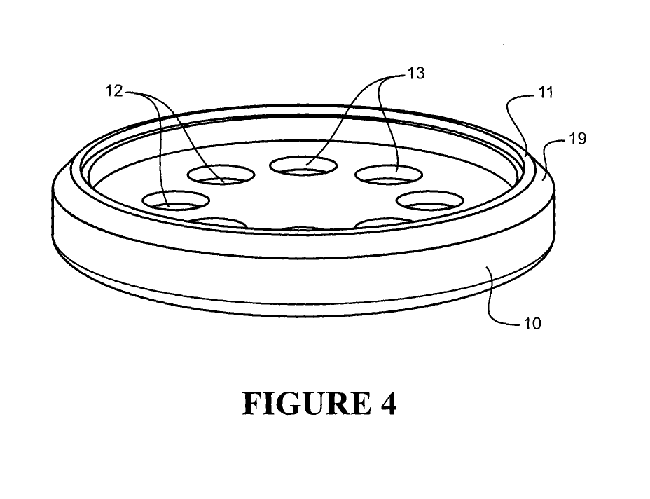

An ion source 1 according to the invention is shown in the isometric view of FIG. 1, the cross-sectional view of FIG. 2, and by the exploded view of the major components in FIGS. 3A to 3F, when taken together.

The major components of the ion source are each generally circular and share a common axial centreline 9. The major components of the ion source are, in the order shown in FIGS. 3A to 3F:
a first cathode pole piece 10,
a anode 20,
a circular array of permanent rare earth magnets 30,
a gas manifold 40,
a second cathode pole piece 50, and
a coolant jacket 60.

The two cathode pole pieces are made from soft or mild steel and are spaced apart from one another to form a cavity 2 therebetween. A circular edge 11 of the first cathode pole piece 10 is spaced apart from a circular edge 51 of the second cathode pole piece 50 to define a circular cathode gap 3 between the respective edges of the pole pieces. A rabbet 18, 58 at the radially inner portion of the edge 11, 51 of each cathode pole piece 10, 50 provides clearance for the anode 20. A radially outer portion 19, 59 of each of the edges 11, 51 of the cathode pole pieces 10, 50 is bevelled at 45 degrees.

The circular anode 20 is made from a non-magnetic conductor for example aluminium, titanium, copper or silver. The anode is spaced apart from both cathode pole pieces 10, 50, and is located in the cavity 2, just inside the cathode gap 3.

The gas manifold 40 is clamped between the first cathode pole piece 10 and the second cathode pole piece 50, with respective opposite end faces at the topside 41 and the underside 42 of the gas manifold in abutment with the two cathode pole pieces. The gas manifold 40 is thermally-conductive and non-magnetic, and is preferably made from copper or aluminium. The gas manifold acts as a heat sink body which helps transfer heat away from the ion source during operation.

As best seen in the cross-sectional view of FIG. 5, the gas manifold 40 incorporates an array of eight radial passageways 43 which extend radially outward, from a threaded blind hole 46 at the centre of the end face at the underside 42 of the gas manifold, to trifurcated outer ends terminating at gas outlet orifices 44 at the circumferential perimeter 45 of the gas manifold. Gas is introduced at a central connector (not shown) in the threaded blind hole 46 and discharged at the gas outlet orifices 44 adjacent the anode 20.

In one embodiment, the first and second cathode pole pieces 10, 50 are magnetised respectively with opposite polarities by eight permanent neodymium rare earth magnets 30 that are evenly arranged in the cavity 2 in a circular array about the axial centreline A-A of the ion source 1. Each magnet has a strength of about 8,000 to 9,000 gauss.

It will be appreciated that the magnet(s) in a further embodiment comprise at least one electromagnet.

The magnets 30 are cylindrical, are axially aligned with the axial centreline 9 of the ion source 1, and are located in respective cylindrical cavities 47 in the gas manifold 40.

The magnets 30 are clamped between the first cathode pole piece 10 and the second cathode pole piece 50. The end face 31 of one magnetic pole of each magnet 30 is in abutment with an end wall 12 of a respective cylindrical well 13 formed in the first cathode pole piece 10. The face 32 of the opposite magnetic pole of each magnet 30 is in abutment with an end wall 52 of a respective cylindrical well 53 formed in the second cathode pole piece 50.

The magnets are each arranged with a common magnetic polarity, e.g. all north poles are in abutment with the first cathode pole piece 10 and all south poles are in abutment with the second cathode pole piece 50, or vice versa.

If the magnets are to be removed from the pole pieces, a screw (not shown) is screwed into a threaded hole 14, 54 provided in the bottom of each well 13, 53 of the pole pieces to force the respective magnet from the well against the magnetic attraction between magnet and pole piece.

An insulated electrical feedthrough connection (not shown) extends from outside the ion source to the anode 20 for connection of an external voltage source to the anode 20. The feedthrough connection, which can be made from a sparkplug, is fitted in threaded hole 55 in the second cathode pole piece 50. One end of a compression spring (not shown) is fitted over the centre electrode of the feedthrough or spark plug, and the other end of the compression spring is fitted over a peg 21 located on the underside of the anode 20, to make electrical contact between the feedthrough connection and the anode. When the ion source is assembled, the feedthrough connection is located in a clearance hole 61 provided in the coolant jacket 60 in alignment with threaded hole 55 in the second cathode pole piece 50.

The circular cathode gap 3 and the circular anode 20 extend through 360 degrees in respective concentric coplanar circles centred on the axial centreline 9 of the ion source.

The anode 20 is supported by four electrically-insulating cylindrical standoffs 48 (only one of which is shown in FIG. 3D). The standoffs 48 are located in respective radially-aligned blind holes 49 in the circumferential perimeter 45 of the gas manifold 40. In one embodiment the standoffs are made from a machinable glass ceramic material exhibiting good electrical insulation, low thermal expansion, low outgassing, and operating temperatures up to about 1000° C.

In other embodiments the standoffs are made from polyimides or thermoplastics.

The coolant jacket 60 abuts with, and is attached to, the lower face 56 of the second cathode pole piece 50. The coolant jacket is made from a thermally-conductive non-magnetic material, preferably aluminium or copper. Four threaded screws (not shown) are located in respective clearance holes 62 provided just inside the perimeter of the coolant jacket, and are screwed into corresponding threaded blind holes (not shown) in the second cathode pole piece 50. A further four screws (not shown) pass through respective clearance holes 63 provided nearer the centre of the coolant jacket and are screwed into corresponding threaded holes 57 (seen in FIGS. 2 and 3E) in the second cathode pole piece 50. These eight screws maintain the coolant jacket in close thermally-conductive abutment with the second cathode pole piece.

Externally pumped coolant from an external source (not shown) enters the coolant jacket 60 via a threaded coolant inlet connector (not shown) that is screwed into a threaded off-centre blind inlet hole 64 in the underside of the coolant jacket. The coolant then passes successively through legs of a rectangular passageway 65, and exits the coolant jacket 60 via a threaded coolant outlet connector (not shown) that is screwed into a second threaded off-centre blind outlet hole 66.

Preferred form coolants include deionised water, transformer oil, helium, fluorocarbon-based fluids, or deodorised kerosene.

Circulation of the coolant is used to cool the ion source. In particular, the ion source is cooled to maintain the temperature of the magnets below a maximum operating temperature, typically 137° C., to ensure the magnets remain below the Curie temperature at which the magnetic strength is reduced and/or irreversibly impaired.

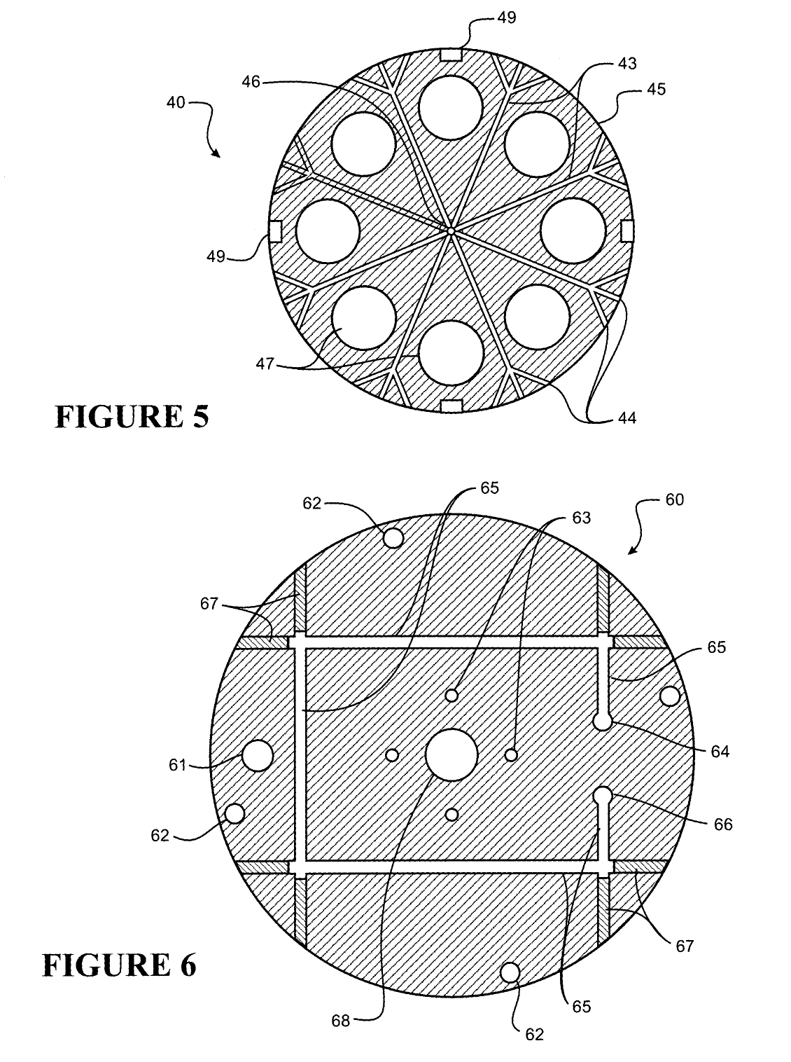

The rectangular passageway 65 is machined in the coolant jacket by drilling five holes, three being through holes and the other two being aligned blind holes that terminate at the blind holes 64, 66 provided in the underside of the coolant jacket. The outer ends of the five drilled holes are sealed with plugs 67 (seen in FIGS. 3F and 6), leaving the rectangular passageway 65 running between the inlet hole 64 and outlet hole 66.

A central hole 68 in the coolant jacket 60, and a central hole 58 in the second cathode pole piece 50, provide clearance for the gas inlet connector (not shown) that is located in these holes and is threaded into the central bore 46 at the underside 42 of the gas manifold 40.

The magnetic attraction between the magnets 30 and the respective cathode pole pieces 10, 50 is sufficient to securely clamp the magnets and the gas manifold 40 between the two cathode pole pieces. Mechanical fasteners are not necessary. The screws described above are for securing the coolant jacket 60 to the second cathode pole piece 50, and for separating the cathode pole pieces 10, 50 from the magnets 30 when disassembling the ion source.

The ion source is assembled substantially as shown in FIGS. 1 and 2, and is operated by connecting a first positive voltage source (not shown) to the anode 50, via the electrical feedthrough fitted in the threaded hole 55 and the compression spring fitted on the peg 21 of the anode 50, and a second positive voltage source, of lower voltage than the first, to the coolant jacket 60 or to either of the cathode pole pieces 10, 50. It is to be appreciated that the coolant jacket, the gas manifold, the magnets and the two cathode pole pieces are in electrical contact with one another and are therefore all at the same electrical potential.

In a typical application the cathode voltage is about 5 to 10 kV and the anode voltage is about 1 to 3 kV higher. In one embodiment, a single voltage source is used, supply the higher voltage directly, and dropping the higher voltage through a series chain of Zener diodes to obtain the lower voltage. In practice, operating voltages as high as 30 kV, or 100 kV, or more, are possible. Operating voltages will likely be limited in particular cases by voltage breakdown between the cathode pole pieces and external objects in close proximity, or by voltage breakdown of the mechanisms supporting the ion source. Limitations on maximum operating voltages may also need to be imposed to avoid generation of X-rays.

A source of process gas, for example nitrogen, is connected to the blind hole 46 at the centre of the underside 42 of the gas manifold 40, to deliver the gas through the trifurcated radial passageways 47 and discharge the gas from the gas outlet orifices 44 into the cavity 2, adjacent the anode 20.

The ion source is operated under a vacuum in the range of 10⁻⁵ to 10⁻³ mbar: i.e. 0.00001 to 0.001 mbar. At these pressures, and with high voltages applied and the gas delivered to the cavity, as described above a plasma is generated at the cathode gap 3, between the bevelled faces 19, 59 of the cathode pole pieces. Nitrogen ions are stripped from the plasma and directed radially outwardly from the full circumference of the ion source. Ions are directed outwardly around 360 degrees in a plane that is substantially perpendicular to the central axis of the ion source. This flat, 360 degree, beam pattern is particularly suited to the implantation of ions at the inner walls and/or outer walls of a tube or pipe. The ion source is supported coaxially in the tube or pipe and traversed through the length of a tube or pipe to treat the full length.

Alternatively the ion source is arranged around at least part of the exterior of a tube or pipe to selectively coat the outer surface of the tube or pipe.

The implanted nitrogen ions form hard bonds with the metal atoms at the surface of the inner wall or outer wall of the tube or pipe, forming hard Fe—N and Al—N bonds, respectively, in the case of steel and aluminium tubes or pipes.

In one application, the ion source 1 according to the current invention, and as described above, is used to implant gas ions at the inner wall surface or outer wall surface of a tube or pipe and thereby provide a physical and/or chemical modification of the wall surface. The tube or pipe is preferably metallic, for example steel, stainless steel, or aluminium. The ion source 1 is located in a portion of the tube or pipe. Voltages, as described above, are applied to the cathode pole pieces 10, 50 and to the anode 20, with a voltage differential between the anode and the cathode pole pieces. The voltages are derived from an electrical power supply that is external to the portion of tube or pipe. The voltages have a positive polarity with respect to the inner wall of the portion of the tube or pipe, which is preferably at earth or ground potential.

In order to implant ions at the inner wall surface of the tube or pipe, the pressure within the portion of the tube or pipe is lowered, if necessary sealing the opposite ends of the portion of the tube of pipe, at least to a rough vacuum, typically 0.001 mbar. To implant ions at an outer wall surface of the tube or pipe, the tube or pipe is preferably located within a larger diameter tube or pipe. The ends of the larger diameter tube or pipe are sealed if necessary.

Nitrogen gas is introduced into the cavity 2 between the cathode pole pieces 10, 50, adjacent the anode 20. The gas is introduced via the gas inlet hole 46, the radial trifurcated passageways 43, and the gas outlet orifices 44. The gas is ionised to produce a plasma at the cathode gap 3 between the bevelled edges 19, 59 of the cathode pole pieces 10, 50. Ions from the plasma are accelerated toward, and implanted in, the inner surface of the wall of the portion of tube or pipe, up to a depth of about 5 nm, equivalent to about 20 atoms.

In one embodiment, the circular cathode pole pieces 10, 50 have an outer diameter of about 140 mm and a depth of about 18 mm, the distance between the edges 11, 51 of the cathode pole pieces is about 4 mm, the outer diameter of the anode 50 is about 120 mm, each of the magnets 30 has a diameter of about 18 mm and a length of about 28 mm, the depth of the magnet-accommodating wells 13, 53 in the cathode pole pieces is about 4 mm, the gas outlet orifices 44 have a diameter of about 3 mm, the gas manifold 40 has a diameter of about 106 mm and a thickness of about 20 mm, the coolant jacket 60 has a diameter of about 140 mm and a thickness of about 13 mm. In one application, this ion source is located coaxially in a tube or pipe having a circular cross-section and an inside diameter of about 160 mm, giving a clearance of about 10 mm between the ion source and the inner wall of the tube or pipe.

The distance between ion source and the inner wall of the tube or pipe is typically in the range from about 10 to 100 mm. The lower limit is governed by avoidance of arc discharge between the ion source and the wall of the tube or pipe. The upper limit is governed by a fall-off in ion implantation when ions have insufficient energy to reach the wall with sufficient energy to provide effective bonding.

The source can be used with a wide range of process gases including, but not limited to, nitrogen, silane and silicon dioxide. Further process gases include a mix of ammonia and titanium tetrachloride to implant TiN or a carbon rich gas such as acetylene or butane to implant metal carbonitrides.

High ion beam currents can be achieved, typically in the range of 1 to 200 mA at about 5 kV.

In an alternative embodiment, the anode 20 is subdivided into segments which extend circumferentially about the central axis 9, with each segment being selectively connected to the high voltage supply via a respective connector in the manner already described above. This enables selection of the arc or arcs through which the ion beam is emitted. It is envisaged that ions may be selectively implanted against subsections of the wall of the tube or pipe. For example, where ions are implanted to improve resistance to abrasion, erosion or corrosion, and the tube or pipe includes a bend, it may be desirable to concentrate the implantation of ions at the inner wall surface around the outer wall of the bend in the tube or pipe, where the degree of abrasion, erosion or corrosion could be expected to be greatest. The selected segment of circumference results in, for example, a 120 degree ion beam.

In high power applications, a second coolant jacket may be used. The second coolant jacket is mounted against the outer surface of the first cathode pole piece 10 and is similar to the coolant jacket 60 described above. Suitable modifications are made to the ion source for passage of coolant water from the first coolant jacket, through the second cathode and gas manifold, to the second coolant jacket, and back.

Wheels, guides or sliders, can be mounted at spaced locations around the periphery of the ion source to maintain the ion source in coaxial alignment inside the tube or pipe. These wheels, guides or sliders are electrically insulated to maintain electrical isolation between the ion source and the tube or pipe.

Although the embodiment described above uses permanent magnets, it is to be understood that one or more electromagnets may be used instead of the permanent magnets to magnetise the cathode pole pieces, as described above.

The foregoing describes the invention including preferred forms thereof. Modifications and improvements as would be obvious to those skilled in the art are intended to be incorporated in the scope hereof as defined by the accompanying claims.

1. An ion source comprising:
first and second cathode pole pieces spaced apart from one another to form a cavity therebetween, an edge of the first cathode pole piece being spaced apart from an edge of the second cathode pole piece to define an elongate cathode gap between the respective edges of the pole pieces, the elongate cathode gap having a longitudinal axis;
at least one magnet arranged for magnetising the first and second cathode pole pieces with opposite magnetic polarities;
an elongate anode located in the cavity, the anode being spaced apart from the first and second cathode pole pieces and having a longitudinal axis, the longitudinal axis of the elongate anode and the longitudinal axis of the elongate cathode gap substantially coplanar;
a first electrical connection which extends from outside the cavity to the anode; and
a gas feed conduit which extends from outside the cavity to inside the cavity for introducing a gas into the cavity.

2. An ion source as claimed in claim 1, wherein the at least one magnet is located in the cavity.

3. An ion source as claimed in claim 2, wherein the at least one magnet is at least one permanent magnet.

4. An ion source as claimed in claim 2, wherein the at least one magnet is at least one electromagnet.

5. An ion source as claimed in claim 1, wherein the ion source has a central axis, and the longitudinal axis of the elongate cathode gap and the longitudinal axis of the elongate anode lie on the circumferences of respective concentric circles centred on the central axis.

6. An ion source as claimed in claim 5, wherein the elongate cathode gap extends circumferentially through 360 degrees about the central axis.

7. An ion source as claimed in claim 5, wherein the elongate anode extends circumferentially through 360 degrees about the central axis.

8. An ion source as claimed in claim 5, wherein the at least one magnet comprises a plurality of magnets located in the cavity, and the magnets are arranged in a circular array centred on the central axis for magnetising the first and second cathode pole pieces respectively with opposite magnetic polarities.

9. An ion source as claimed in claim 8 wherein:
a thermally-conductive heat sink body is clamped between the cathode pole pieces with opposite end faces of the heat sink body respectively in abutment with the first and second cathode pole pieces;
each magnet is clamped between the first and second cathode pole pieces with a north pole face of each magnet in abutment with one cathode pole piece and a south pole face of each magnet in abutment with the other cathode pole piece;
the magnets are located in respective cavities in the heat sink body; and
the gas feed conduit comprises an internal passageway which extends substantially radially outward from a central location at one of the end faces of the heat sink body to multiple gas outlets at circumferentially-spaced locations at an outer circumferential face of the heat sink body.

10. An ion source as claimed in claim 9 wherein the anode is supported by at least one electrically insulating standoff, and the at least one standoff is supported by the heat sink body.

11. An ion source as claimed in claim 9 wherein a heat extractor is held in abutment with one of the pole pieces, the heat extractor comprising a thermally conductive body with an internal passageway which extends between a coolant inlet and a coolant outlet which are located at a face of the heat sink body.

12. An ion source as claimed in claim 5, wherein segments of the elongate anode extend circumferentially about the central axis, and the ion source comprises a respective electrical connection extending from outside the cavity to each segment of the anode.

13. A method of implanting ions at an inner wall surface of a tube or pipe, comprising:
locating an ion source as claimed in claim 1 inside a portion of the tube or pipe;
connecting a first voltage source to the or each electrical connection which extends from outside the cavity to the or each anode;
connecting a second voltage source to the first and second cathode pole pieces,
creating at least a partial vacuum in the portion of the tube or pipe;
introducing a gas into the cavity through the gas feed conduit;
ionising gas in the cathode gap to produce a plasma; and
directing gas ions from the plasma to the inner wall surface of the tube or pipe.

14. A method of implanting ions at an outer wall surface of a tube or pipe, comprising:
locating an ion source as claimed in claim 1 around at least part of the exterior of a portion of the tube or pipe;
connecting a first voltage source to the or each electrical connection which extends from outside the cavity to the or each anode;
connecting a second voltage source to the first and second cathode pole pieces,
creating at least a partial vacuum in the portion of the tube or pipe;
introducing a gas into the cavity through the gas feed conduit;
ionising gas in the cathode gap to produce a plasma; and
directing gas ions from the plasma to the outer wall surface of the tube or pipe.

15. A method of implanting ions as claimed in claim 13 wherein the ion source is as claimed in claim 5, and the ion source is located coaxially with the longitudinal axis of the portion of the tube or pipe.

16. A method of implanting ions as claimed in claim 13, comprising advancing the ion source axially along the tube or pipe.

17. A method of implanting ions as claimed in claim 13, wherein the elongate cathode gap extends circumferentially through 360 degrees about the central axis, the elongate anode extends circumferentially through 360 degrees about the central axis, and gas ions from the ion source are directed through 360 degrees simultaneously toward the full circumference of the wall surface of the tube or pipe.

18. A method of implanting ions as claimed in claim 13, wherein segments of the elongate anode extend circumferentially about the central axis, and the ion source comprises a respective electrical connection extending from outside the cavity to each segment of the anode, and the first voltage is selectively connected to one or more segments of the anode via the respective electrical connections to direct gas ions from the ion source through an arc of less than 360 degrees toward a portion of the circumference of the wall surface of the tube or pipe.

19. A method of implanting ions as claimed in claim 18, wherein the portion of the tube or pipe is curved and the first voltage is selectively connected to one or more of the anode segments to direct gas ions toward the wall surface of the tube or pipe at an outer side of the curved portion of tube or pipe.
